(19) United States
(12) Patent Application Publication
(10) Pub. No.: US 2017/0098552 A1
(43) Pub. Date: Apr. 6, 2017

(54) Processed Substrate Surface For Epoxy Deposition And Method Thereof

(71) Applicant: Inspiraz Technology Pte. Ltd., Singapore (SG)

(72) Inventors: Kim Wee TAN, Singapore (SG); Cheng Lam NG, Singapore (SG)

(21) Appl. No.: 15/281,094

(22) Filed: Sep. 30, 2016

(30) Foreign Application Priority Data
Oct. 2, 2015 (SG) 10201508196Y

(51) Int. Cl. H01L 21/56; H01L 23/31; B05D 1/00

(52) U.S. Cl. CPC H01L 21/565; B05D 1/60; H01L 23/3114

(57) ABSTRACT

The present invention provides a method for treating a substrate having a surface of deposition, the method comprises providing a hydrophilic coating over the surface of the substrate; and providing a hydrophobic coating on an area of deposition, wherein the area is a dedicated area over the surface of deposition. The dedicated area attributes a contrasting liquid attracting-repelling properties against a remaining area outside the area of deposition. The substrate treated with the above method is also provided.

### FIELD OF INVENTION

The present invention relates to epoxy flow to control the pattern. More particularly, to method for processing a surface for depositing low viscosity epoxy in a controlled shape or pattern.

### BACKGROUND

Die attaching process is part of the Integrated Circuit (IC) packaging for attaching the singulated die on the IC board. The quality of the bond between the die and substrate can be critical in defining the ultimate product quality and reliability.

Epoxies, conductive or non-conductive, have been widely used in the various processes and purposes of IC packaging. When the epoxy is used, operationally, a predetermined amount of epoxy is deposited/extruded on the surface of interest. It is well known in the art that epoxies exhibit complex reactions to even simple shear conditions due to their shear thinning and viscoelastic characteristics.

Applications of the epoxy on IC packaging include die encapsulation, die attach, and flip chip under-fill as shown in FIGS. 1A-1C respectively.

In FIG. 1A, the die is mounted onto the leadframe or printed circuit board. After it is wire-bonded, the epoxy is extruded to encapsulated therein. It would be desired that the extruded epoxy be controlled to seal the die therein.

In FIG. 1B, the die is attached to the die bonding pad via epoxy. Liquid epoxy is deposited over the die bonding pad and the die is positioned over it. And the die is being pressed down against the bond pad, the epoxy flows across the bond pad. Without a proper control over the epoxy flow, different issues may occur, including insufficient epoxy, overflow or void

For flip chip under-fill as shown in FIG. 1C, the epoxy is extruded along the bottom sides of the die. As the die has solder balls attached therein, the epoxy fills up the underneath gaps. Similarly, without the proper control over at the epoxy flow, the epoxy may not be able to fill up the underneath gaps properly.

In many applications, the liquid epoxy is to be deposited to form a specific pattern on the deposition surface. As much as the patterns can be derived through known mathematical equations or models, in practice, the epoxy deposited on the deposition surface may not stay in the shapes or patterns as desired.

As shown in FIG. 2, a small amount of liquid epoxy is extruded on a surface as shown on the left. Depending on the physical properties of the surface, the liquid epoxy may flow freely and unevenly (as shown on right top) without any deliberate control. Such flow result is undesirable for IC packaging.

To gain a proper control on the fluid flow, it is necessary to understand the surface adhesion property of the deposition surface as well as the viscosity of the epoxy fluid to determine the amount and method of deposition as precise as possible, to gain better control of the fluid flow. On top of that, liquid epoxy may also be deposited in a specific pattern, instead of the round drop, on the deposition surface. As much as the patterns can be derived through known mathematical equations or models, in practice, the epoxies deposited on the deposition surface may not stay in the shapes or patterns as desired.

The common practices used for controlling the epoxy deposition often involve trial and error to fine-tune the deposition and the liquid epoxy flow in achieving the desire result.

To gain a better control, the viscosity of the fluid epoxy is often adjusted accordingly to suit the specific substrate of a specific batch of manufacture from a specific manufacturer. It is a trend that a relatively high viscosity of the epoxy fluid is used, as it is easier to control its flow. Due to the low flow rate, nozzles adapted for dispensing the high viscosity epoxy fluid are commonly configured with a patterned shaped spout so that the liquid can be dispensed at an intended pattern. Such method however is prone to create voids or insufficient dispensing coverage over the desired area of deposition.

It is to be noted that such trial and error method is time consuming and causes wastage on the materials used. It is also known that only the substrate surfaces that are processed on the same batch by the same manufacturer may produce the same or similar result. Practically, another trial and error process maybe needed. Such inconsistency costs wastage on manufacturing cost and cycle time.

Even when a low viscosity is used, it is still impossible to predict and control the epoxy flow.

### SUMMARY

In one aspect of the present invention, there is provided a method for treating a substrate having a surface of deposition, the method comprises providing a hydrophilic coating over the surface of the substrate; and providing a hydrophobic coating on an area of deposition, wherein the area is a dedicated area over the surface of deposition. The dedicated area attributes a contrasting liquid attracting-repelling properties against a remaining area outside the area of deposition.

In one embodiment, the method further comprises masking the surface to cover the area of deposition, so that the hydrophilic coating is applied to the remaining area.

In another embodiment, the method further comprises masking the surface to only expose the area of deposition, so that the hydrophobic coating is applied only to the area of deposition. The mask may adapt with a cutout area that corresponds to a desired shape or pattern or footprint of the area of deposition.

In a further embodiment, the method of claim 1, wherein the hydrophilic coating is a chemical coating.

In yet a further embodiment, the hydrophobic coating may include a gaseous coating or a plasma treatment.

In another aspect, there is also provided a substrate being treated with the aforesaid method.

### BRIEF DESCRIPTION OF THE DRAWINGS

Preferred embodiments according to the present invention will now be described with reference to the figures accompanied herein, in which like reference numerals denote like elements:

FIGS. 1A-1C exemplify various known applications of the liquid epoxy depositions;

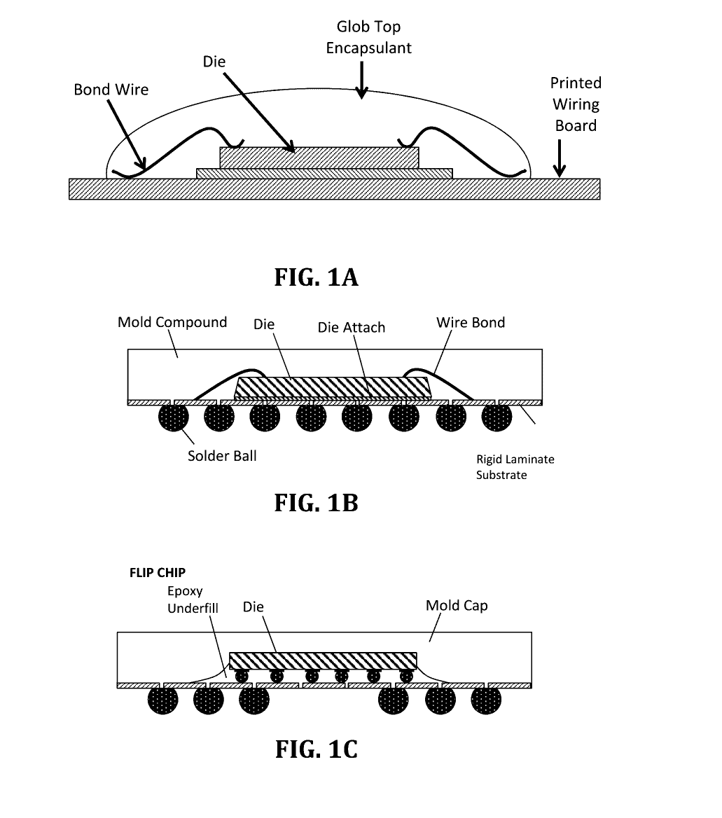

FIG. 2 illustrates schematically the fluid flow;

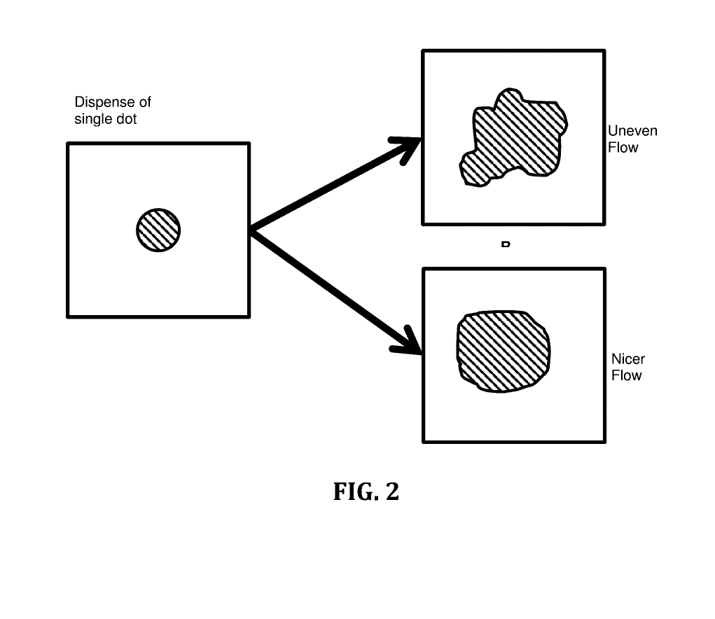

FIGS. 3 and 4 exemplifies two epoxy deposition application in accordance with an embodiment of the present invention;

FIG. 5 illustrates a flow chart of surface treatment in accordance with an embodiment of the present invention;

For simplicity and clarity of illustration, the drawing figures illustrate the general manner of construction and may omit depiction, descriptions, and details of well-known features and techniques to avoid unnecessarily obscuring the exemplary and non-limiting embodiments of the invention described in the subsequent Detailed Description.

### DETAILED DESCRIPTION

In line with the above summary, the following description of a number of specific and alternative embodiments is provided to understand the inventive features of the present invention. It shall be apparent to one skilled in the art, however that this invention may be practiced without such specific details. Some of the details may not be described at length so as not to obscure the invention. For ease of reference, common reference numerals will be used throughout the figures when referring to the same or similar features common to the figures.

It is therefore an object of the present invention to provide a stable and reliable process allowing the epoxy to be deposited at a controlled manner, preferably, be deposited in a desired shape or pattern.

To address the aforesaid problems, the present invention provides a pre-process to treat the deposition surface so that the epoxy can be deposited on the pre-processed surface in a controlled manner. In particular, the epoxy can be deposited on the surface forming a footprint in any desired shape. To achieve that, the present invention pre-processes the surface of deposition allowing the epoxy flows across the intended deposition surface to form a footprint of a desire shape. Through the present invention, the epoxy flow can be formed in a highly controlled and precise shape. Specifically, in one embodiment, the pre-processing causes the area of interest to attribute hydrophilic property, whereby the remaining outside area to attribute hydrophobic property. The relatively high contrast between the two surfaces' attributes allows the liquid epoxy to be effectively controlled in its flow.

In accordance with the present invention, epoxy used may be in lower viscosity relatively.

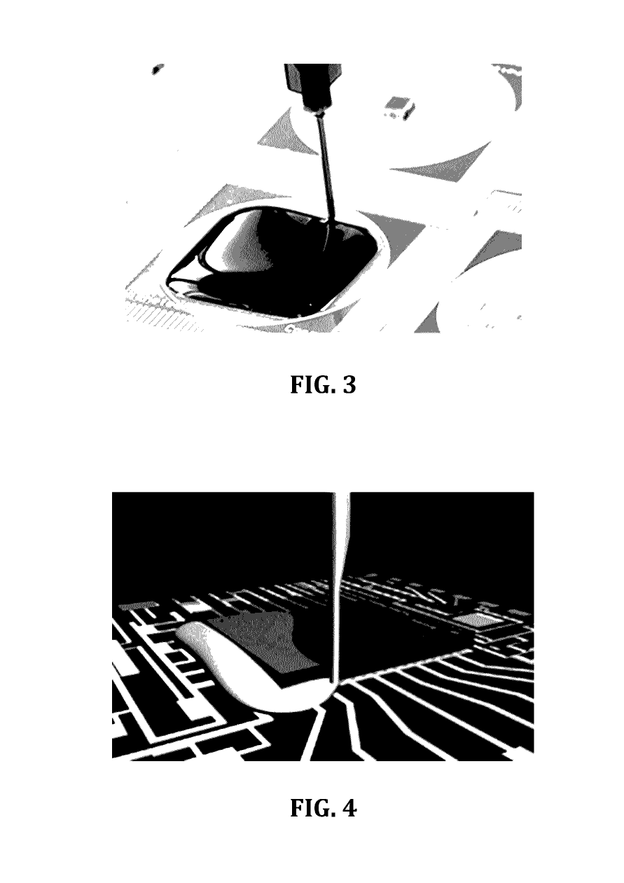

It is an object of the present invention to provide a stable and reliable process with a precise control over the shape of the dispensed epoxy within the substrate as shown in FIGS. 3 and 4. FIG. 3 shows a substrate that has been processed in accordance with an embodiment of the present invention. Liquid epoxy is extruded onto the surface of desired pattern. As it can be seen from the figure, as the epoxy is extruded, it forms a rounded square shape itself.

FIG. 4 shows a surface mount substrate having a chip mounted thereon. The figure shows a flip chip under-fill process. The substrate has been pre-processed in accordance with an embodiment of the present invention. The pre-process changes the adhesion property of the surface. In the case of FIG. 4, the area of deposition is the area underneath the chip. In particular, the pre-process changes the physical property, such as surface tension, on the specific area on the substrate in a manner that the area of deposition has a contrast adhesion property from that of the remaining area, hydrophilic vs. hydrophobic. It is desired that the area of deposition has high adhesive property, whereby the remaining area of the substrate surface has high liquid repelling property. With such configuration, the liquid epoxy extruded around the perimeter of the chip will be drawn into the under space between the chip and the substrate to fill the cap due to the contrast adhesive property between the two areas.

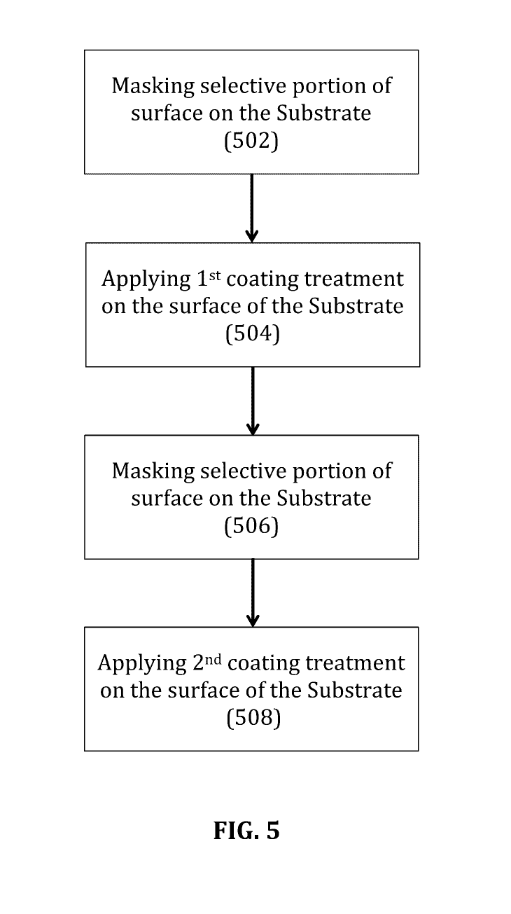

FIG. 5 illustrates a pre-process for treating a substrate before liquid epoxy deposition in accordance with an embodiment of the present invention. The pre-process comprising an optional masking of selective area on the surface of the substrate at step 502; and thereafter applying a first coating treatment on a substrate surface at step 504; masking the substrate at step 506; and exposing the masked substrate to a chemical or gaseous treatment at step 508.

In step 502, an optional process to apply a mask onto the surface of the substrate to cover up the area intended for epoxy deposition.

In the step 504, the entire surface of the substrate is provided with a layer of coating on the substrate. Desirably, the coating gives the surface a high repelling property to liquid, i.e. hydrophobic property. If the optional step 502 above was already applied, the hydrophobic coating will not affect the masked area(s), which was dedicated for depositing the epoxy.

In another embodiment, step 502 is optional for some applications, where there is no need to mask off the area of deposition, and the entire surface of the substrate is coated with the hydrophobic coating.

As the hydrophobic coating is done, a further mask is applied onto the surface of the substrate in step 506. This mask comprises cutout area(s) that corresponds to the area of depositions (of the liquid epoxy), such that the remaining area not intended for deposition of epoxy will be masked off.

In step 508, the unmasked surface of the substrate is exposed to a chemical or gaseous treatment. Under the circumstances, the chemical or gaseous treatment turns the unmasked area of the surface into an area that is relative more receptive to bonding with liquid than the surrounding areas (i.e. the masked surface), i.e. hydrophilic property. That gives a contrasting surface tension between the area(s) of deposition. Accordingly, the surface or portion of surface is pre-treated with a hydrophilic property for deposition of the epoxy, whereby the deposited epoxy flows to fill the treated area only thereby forming the desired shape or pattern. In one illustrative example on chemical treatment, water-attracting chemical can be used for treating the surface to give the surface of interest a hydrophilic property. In an alternative embodiment, gaseous treatment, such as plasma treatment can be used to give the surface of interest a hydrophilic property. In one non-limiting embodiment, Corona Treatment may be desired. In other embodiments, atmospheric plasma or vacuum plasma, or any other plasma treatment can also be desired.

Once the pre-process is completed, the liquid epoxy can be deposited over on the area(s) that is exposed to the treated area mentioned above.

In another embodiment of the present invention, the coating of the surface of the substrate may also be done at the substrate/lead-frame manufacturers' side, whereby the masking and light radiations may be done separately at different stage.

The core of the present invention is to provide means to facilitate epoxy deposition in a controlled manner. Specifically, the present invention provides a substrate that is pre-processed or pre-treated before epoxy deposition. Preferably, the surface of deposition defines a boundary of deposition area whereby the extruded liquid is bound to flow within the boundary or perimeters of the area. The present invention offers a preprocess

Through the process, the epoxy deposition is always consistent regardless of the difference in substrates from different batch and various manufacturers, which would result higher yield, reduced cost and less wastage.

Furthermore, the shape of deposition can be effectively controlled through the mask, or any other equivalent means. Such process does not require any special designed dispensing nozzles to form the desired shaped because the shape can be determined by the mask.

The substrate can be fabricated at the manufacturer side whereby the hydrophobic coating is coated at the manufacturer side before shipping to another party. Then substrate can be run under the hydrophilic creation process over the area and the shape of desired before deposition. Alternatively, both processes can be done at the end user side before the epoxy deposition.

It is appreciated to a skilled person that the embodiments of the present invention aims to provide a substrate that is pre-treated for depositing epoxy over at the area of interest at a controlled manner. The surface pre-treatment causes the substrate surface to consist one or more area attributing contrast water repelling and water attracting behavior, wherein the area of deposition has a more water attracting behavior than the remaining area. Through the present invention, the desire location and shape or pattern of the area of deposition can be precisely determined, and the flow of the epoxy can be restrained within the shaped area.

As illustrated, the present invention provides a deposition area that has a relatively high liquid attracting property than that of the remaining area not intended for epoxy deposition. A high liquid attracting property can be obtained through any suitable hydrophilic treatment. On the other hand, the remaining area may further provided with a relatively high water repelling property, which can be obtain through any suitable hydrophobic treatment.

The illustrations provided in the present application focuses on semiconductor fabrication. A person skilled in the art, however, would appreciate that the present invention can be extended to many other applications that require precise liquid deposition controls, in particular, controls over the shape/footprint formed on the surface of deposition. These applications include, but not limited to, hard disk drive fabrication, flux dispensing on PCB, adhesive/epoxy deposition, biomedical, and etc. To control the fluid deposition, the present invention provides a surface treatment that defines an area of deposition having relatively high adhesion or wetting property over at the remaining area over the same surface. Such contrast in adhesion property causes a boundary defining the area of deposition whereby the liquid deposited within the area of deposition is bound within the area. Best still, it is possible to define the boundary in any shape of desired, literally any shape is possible.

Advantageously, as the surface treatment is done on the surface of the surface of deposition, there is no need to be concerned about the viscosity of the fluid. In particular, the system works well with low viscosity epoxy.

Also as mentioned, due to the contrast in the surface properties between the area of deposition and the remaining area, fluid deposited on the remaining area can be drawn or pushed into the area of deposition due to the liquid repelling property of the remaining area of the treated surface.

As would be apparent to a person having ordinary skilled in the art, the afore-described methods and components may be provided in many variations, modifications or alternatives to existing methods and systems. The principles and concepts disclosed herein may also be implemented in various manners which may not have been specifically described herein but which are to be understood as encompassed within the scope of the following claims.

1. A method for treating a substrate having a surface of deposition, the method comprising:
providing a hydrophobic effect over the surface of the substrate; and
providing a hydrophilic effect on an area of deposition, wherein the area is a dedicated area over the surface of deposition,
thereby the dedicated area attributes a contrasting liquid attracting-repelling properties against a remaining area outside the area of deposition.

2. The method of claim 1, further comprises masking the surface to cover the area of deposition, so that the hydrophobic effect is applied to the remaining area.

3. The method of claim 1, further comprises masking the surface to only expose the area of deposition, so that the hydrophilic effect is applied only to the area of deposition.

4. The method of claim 3, wherein the mask is adapted with a cutout area that corresponds to a desired shape or pattern or footprint of the area of deposition.

5. The method of claim 1, wherein the hydrophilic effect is a chemical or gaseous coating.

6. The method of claim 1, wherein the hydrophobic effect is a chemical or gaseous coating.

7. The method of claim 1, wherein the hydrophobic effect includes a liquid coating or plasma treatment.

8. A substrate being treated in accordance with the method of claim 1.
